(19) United States
(12) Patent Application Publication
(10) Pub. No.: US 2015/0329334 A1
(43) Pub. Date: Nov. 19, 2015

(54) OVERHEAD HOIST TRANSFER SYSTEM AND FACTORY SYSTEM EMPLOYING THE SAME

(71) Applicant: SAMSUNG ELECTRONICS CO., LTD., Suwon-si (KR)

(72) Inventors: Jae-Nam LEE, Asan-si (KR); Seong-Hoon PARK, Seoul (KR); Doo-Jin JUNG, Cheonan-si (KR); Hee-Sang YANG, Asan-si (KR); Sung-Yeol LEE, Cheonan-si (KR)

(73) Assignee: SAMSUNG ELECTRONICS CO., LTD., Suwon-si (KR)

(21) Appl. No.: 14/637,507

(22) Filed: Mar. 4, 2015

(30) Foreign Application Priority Data
May 14, 2014 (KR) 10-2014-0058004

(51) Int. Cl. B66C 19/00; H01L 21/677; B25J 11/00

(52) U.S. Cl. CPC B66C 19/00; B25J 11/0095; H01L 21/67733

(57) ABSTRACT

Provided are an overhead hoist transfer system and a factory system employing the same. The factory system includes a rail attached to a ceiling of a factory. An overhead hoist transfer system, in which a first carrier configured to receive a first material and a second carrier configured to receive a second material may be suspended and moved along the rail, is provided. A processing device system including a first carrier port in which the first carrier may be seated, a first device gate through which the first material may pass, a second carrier port in which the second carrier may be seated, and a second device gate through which the second material may pass, is provided. The processing device system may be adjacent to the rail. The overhead hoist transfer system includes a grip unit configured to grip the first carrier or the second carrier, and a rotating unit configured to rotate the grip unit.

### CROSS-REFERENCE TO RELATED APPLICATION

This application claims priority from Korean Patent Application No. 10-2014-0058004, filed on May 14, 2014, in the Korean Intellectual Property Office, the disclosure of which is incorporated herein by reference in its entirety.

### BACKGROUND

1. Technical Field

Systems consistent with exemplary embodiments relate to an overhead hoist transfer system capable of suspending a carrier in which a material is carried and/or stored and moving the carrier to a desired location, and a factory system employing the same.

2. Description of Related Art

Factory systems can include various processing devices. Materials provided and/or received to/from the processing devices can be loaded to carriers, and the carriers can be moved by overhead hoist transfer systems.

### SUMMARY

In accordance with an aspect of an exemplary embodiment, a factory system includes a rail attached to a ceiling of a factory. An overhead hoist transfer system, in which a first carrier configured to receive a first material and a second carrier configured to receive a second material may be suspended and moved along the rail, is provided. A processing device system including a first carrier port in which the first carrier may be seated, a first device gate through which the first material may pass, a second carrier port in which the second carrier may be seated, and a second device gate through which the second material may pass, is provided. The processing device system may be adjacent to the rail. The overhead hoist transfer system includes a grip unit configured to grip the first carrier or the second carrier, and a rotating unit configured to rotate the grip unit.

In an exemplary embodiment, a first direction from the first carrier port to the first device gate may be different from a second direction from the second carrier port to the second device gate.

In an exemplary embodiment, the first device gate may have a first size to allow the first material to be passed in and out of the first device gate, and the second device gate may have a second size different from the first size to allow the second material to be passed in and out of the second device gate, wherein the first material may comprise a semiconductor wafer, and the second material may comprise a semiconductor die, a semiconductor chip, and a printed circuit board.

In an exemplary embodiment, the overhead hoist transfer system may further include a drive unit configured to drive along the rail, a body connected to the drive unit and having an inner space in which a bottom portion and two side portions of the body are open, a sliding unit connected to the body, and a hoist unit disposed under the sliding unit.

In an exemplary embodiment, the hoist unit may be connected to the rotating unit.

In an exemplary embodiment, the rotating unit may include a rotating shaft and a rotary drive motor configured to rotate the rotating shaft, and the rotating shaft of the rotating unit may be connected to the grip unit.

In accordance with an aspect of another exemplary embodiment, an overhead hoist transfer system includes a drive unit, a body connected at a lower part of the drive unit, a sliding unit connected to the body, a grip unit disposed under the sliding unit and holding a carrier, and a hoist unit and a rotating unit, which are disposed between the sliding unit and the grip unit and connected to each other.

In an exemplary embodiment, the body may have an inner space in which two side portions and a bottom portion of the body are open.

In an exemplary embodiment, the body may include a front body part, a rear body part facing the front body part, and an upper body part connecting an upper part of the front body part to an upper part of the rear body part.

In an exemplary embodiment, a control system may further be included, wherein the control system may include a front side detecting sensor and a lower side detecting sensor, which are disposed on the front body part.

In an exemplary embodiment, a carrier fixing device connected to the body may further be included, wherein the carrier fixing device may include a first carrier fixing device disposed in a lower area of the front body part, and a second carrier fixing device disposed in a lower area of the rear body part.

In an exemplary embodiment, each of the first and second carrier fixing devices may include a drive part, a carrier fixing part, and a buffer part, wherein the drive part may be disposed on the body, the carrier fixing part may have a part protruding from the body and may be disposed to move in horizontally reciprocating directions by the drive part, and the buffer part may have a part, which contacts the carrier by the horizontal reciprocating motion of the carrier fixing part.

In an exemplary embodiment, the inner space of the body may have a first space having a first width and a second space having a second width greater than the first width.

In an exemplary embodiment, the sliding unit may be disposed in the first space, and the carrier held by the grip unit may be located in the second space.

In an exemplary embodiment, the sliding unit may include a sliding plate configured to move to a desired side of the open two side portions of the body, the hoist unit may include a hoist wire configured to lower or raise the grip unit, and the rotating unit may include a rotary drive motor and a rotating shaft, the rotary drive motor being configured to directly or indirectly rotate the grip unit.

In an exemplary embodiment, one of the hoist unit and the rotating unit may be connected to the sliding unit, and another one of the hoist unit and the rotating unit may be connected to the grip unit.

In accordance with an exemplary embodiment, an overhead hoist transfer system includes a drive unit configured to drive along a rail attached to a ceiling of a factory, a body connected at a lower part of the drive unit and having an inner space in which a bottom portion and two side portions of the body are open, a sliding unit connected to the body and disposed in the inner space of the body, a grip unit disposed under the sliding unit, configured to hold a carrier, in which a material is loaded, and located in the inner space of the body, and a hoist unit and a rotating unit, which are disposed between the sliding unit and the grip unit and connected to each other.

In an exemplary embodiment, the rotating unit may be disposed between the grip unit and the hoist unit, and directly connected to the grip unit.

In an exemplary embodiment, the rotating unit may include a rotating shaft and a rotary drive motor configured to rotate the rotating shaft.

In an exemplary embodiment, a carrier fixing device connected to the body may further be included, wherein the carrier fixing device may include a carrier fixing part protruding from the body to face the carrier located in the inner space of the body, a drive unit disposed inside the body and configured to move the carrier fixing part in horizontally reciprocating directions, and a buffer part including a part formed on an end of the carrier fixing part and directly contacting the carrier by a horizontal reciprocating motion of the carrier fixing part.

### BRIEF DESCRIPTION OF THE DRAWINGS

The above and/or other aspects will become apparent and more readily appreciated from the following description of the exemplary embodiments, taken in conjunction with the accompanying drawings in which:

FIG. 1 is a schematic view showing a factory system including an overhead hoist transfer system in accordance with an exemplary embodiment;

FIG. 2 is a schematic block diagram showing an overhead hoist transfer system in accordance with an exemplary embodiment;

FIG. 3A is a side view showing an overhead hoist transfer system in accordance with an exemplary embodiment;

FIG. 3B is a perspective view showing an overhead hoist transfer system in accordance with an exemplary embodiment;

FIG. 3C is a view showing a part of an overhead hoist transfer system in accordance with an exemplary embodiment;

FIGS. 4A and 4B are perspective views for describing an internal structure of a rotating unit of an overhead hoist transfer system in accordance with exemplary embodiments;

FIG. 5 is a perspective view for describing a rotating unit and a grip unit of an overhead hoist transfer system in accordance with an exemplary embodiment;

FIG. 6A is a side view showing an overhead hoist transfer system in accordance with an exemplary embodiment;

FIG. 6B is a perspective view showing an overhead hoist transfer system in accordance with an exemplary embodiment;

FIG. 7 is a schematic block diagram showing an overhead hoist transfer system in accordance with an exemplary embodiment;

FIG. 8 is a side view showing an overhead hoist transfer system in accordance with an exemplary embodiment;

FIG. 9 is a side view showing an overhead hoist transfer system in accordance with an exemplary embodiment;

FIG. 10 is a side view showing an overhead hoist transfer system in accordance with an exemplary embodiment;

FIG. 11 is a side view showing an overhead hoist transfer system in accordance with an exemplary embodiment; and

FIGS. 12A, 12B, 12C, 12D and 12E are top views showing a factory system including an overhead hoist transfer system in accordance with exemplary embodiments.

### DETAILED DESCRIPTION

Example embodiments will now be described more fully with reference to the accompanying drawings, in which various exemplary embodiments are shown. The exemplary embodiments may, however, be embodied in various different forms, and should not be construed as limited to the exemplary embodiments set forth herein. Rather, the exemplary embodiments are provided so that this disclosure is thorough and complete and fully conveys the scope of the exemplary embodiments to those skilled in the art. In the drawings, the sizes and relative sizes of layers and regions may be exaggerated for clarity. The same reference symbols denote the same components throughout the specification.

The exemplary embodiments are described herein with reference to cross-sectional views, plan views, and/or block diagrams that are schematic illustrations of idealized embodiments of the exemplary embodiments. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. Therefore, regions illustrated in the drawings are schematic in nature, and their shapes are not intended to limit the scope of the exemplary embodiments but only to illustrate characteristic forms of regions of devices.

The thicknesses of layers and regions in the drawings may be exaggerated for the sake of clarity. Further, it will be understood that when a layer is referred to as being “on” another layer or a substrate, the layer may be formed directly on the other layer or the substrate, or there may be an intervening layer therebetween. The same reference numerals indicate the same components throughout the specification.

Terms such as “top,” “bottom,” “upper,” “lower,” “above,” “below,” and the like are used herein to describe the relative positions of elements or features. It will be understood that such descriptions are intended to encompass different orientations in use or operation in addition to orientations depicted in the drawings. For example, when an upper part of a drawing is referred to as a “top” and a lower part of a drawing as a “bottom” for the sake of convenience, in practice, the “top” may also be called a “bottom” and the “bottom” a “top” without departing from the teachings.

Furthermore, throughout this disclosure, directional terms such as “upper,” “intermediate,” “lower,” and the like may be used herein to describe the relationship of one element or feature with another, and the exemplary embodiments should not be limited by these terms. Accordingly, these terms such as “upper,” “intermediate,” “lower,” and the like may be replaced by other terms such as “first,” “second,” “third,” and the like to describe the elements and features.

It will be understood that, although the terms “first,” “second,” etc. may be used herein to describe various elements, these elements should not be limited by these terms. These terms are only used to distinguish one element from another. Thus, a first element could be termed a second element without departing from the teachings of the exemplary embodiments.

The terminology used herein to describe embodiments of the invention is not intended to limit the scope of the invention.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which the exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

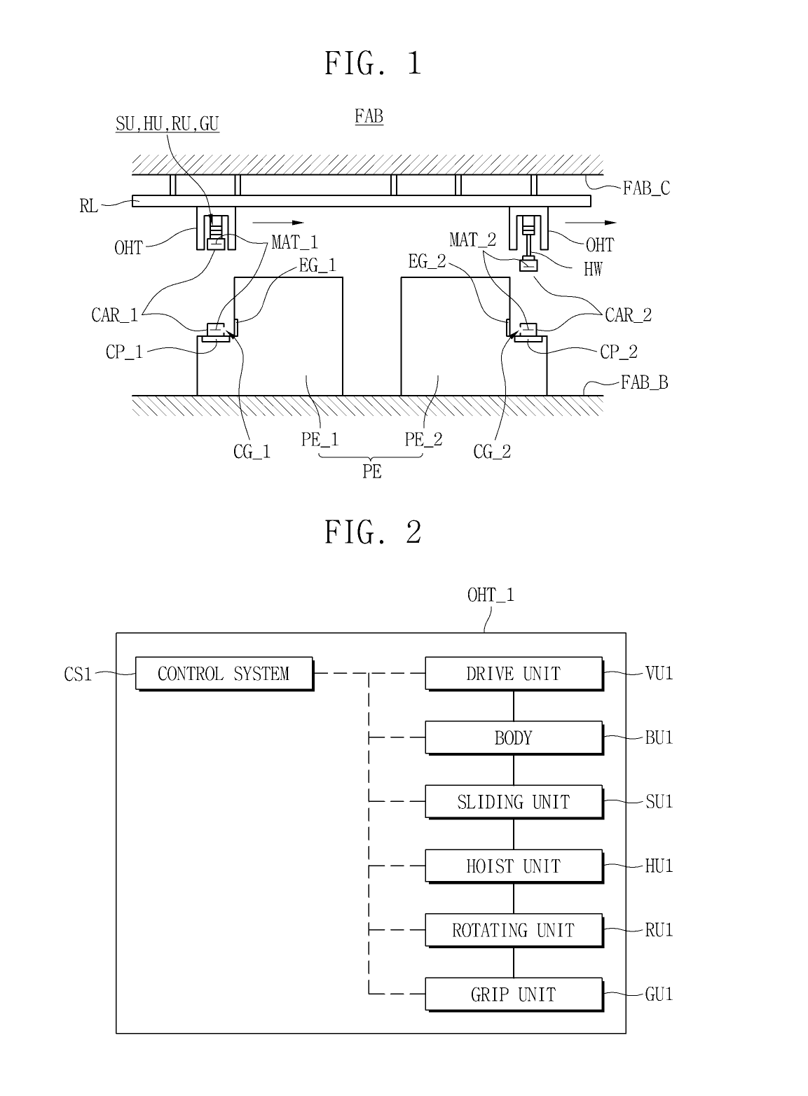

FIG. 1 is a schematic view showing a factory system including an overhead hoist transfer system in accordance with an exemplary embodiment.

Referring to FIG. 1, a factory system FAB may include a rail RL attached and continuously connected to a ceiling FAB_C of a factory, an overhead hoist transfer system OHT capable of driving or moving along the rail RL, and a processing device system PE disposed on a bottom FAB_B of the factory.

The overhead hoist transfer system OHT may suspend a first carrier CAR_1 capable of receiving a first material MAT_1 and a second carrier CAR_2 capable of receiving a second material MAT_2, and drive along the rail RL.

The first material MAT_1 and/or the second material MAT_2 may include a material, such as a semiconductor wafer, a semiconductor chip, a printed circuit board, or the like, used for manufacturing a semiconductor device.

The first carrier CAR_1 and the second carrier CAR_2 may have a tool for stacking or constantly loading the first material MAT_1 or the second material MAT_2, and storing and/or carrying the first material MAT_1 or the second material MAT_2. For example, the first carrier CAR_1 or the second carrier CAR_2 may include a magazine, a wafer cassette, a front opening shipping box (FOSB), or a front opening united pod (FOUP).

The first carrier CAR_1 may have a first carrier gate CG_1 through which the first material MAT_1 may pass in or out. The second carrier CAR_2 may have a second carrier gate CG_2 through which the second material MAT_2 may pass in or out.

The processing device system PE may include a first carrier port CP_1 in which the first carrier CAR_1 may be seated, a first device gate EG_1 through which the first material MAT_1 may pass in or out, a second carrier port CP_2 in which the second carrier CAR_2 may be seated, and a second device gate EG_2 through which the second material MAT_2 may pass in or out.

The first and second carrier ports CP_1 and CP_2 may be disposed around the rail RL, which is continuously connected. A direction from the first carrier port CP_1 to the first device gate EG_1 may be different from a direction from the second carrier port CP_2 to the second device gate EG_2.

The processing device system PE may include processing devices to be used in front-end processes and/or back-end processes for manufacturing a semiconductor device. For example, the processing device system PE may include a first processing device PE_1 having the first carrier port CP_1 and the first device gate EG_1, and a second processing device PE_2 having the second carrier port CP_2 and the second device gate EG_2.

The overhead hoist transfer system OHT may include a grip unit GU capable of holding or releasing the first carrier CAR_1 or the second carrier CAR_2, a rotating unit RU capable of directly or indirectly rotating the grip unit GU, a sliding unit SU capable of moving the grip unit GU so that the grip unit GU is located on any one port of the first and second carrier ports CP_1 and CP_2, and a hoist unit HU capable of lowering or raising the grip unit GU. The grip unit GU may be lowered or raised while a hoist wire HW of the hoist unit HU is released or wound in.

The rotating unit RU may rotate the first carrier CAR_1 so that the first carrier gate CG_1 of the first carrier CAR_1 faces the first device gate EG_1. The rotating unit RU may rotate the second carrier CAR_2 so that the second carrier gate CG_2 of the second carrier CAR_2 faces the second device gate EG_2. The first and second carrier gates CG_1 and CG_2 may include gates through which the first and second materials MAT_1 and MAT_2 loaded in the first and second carriers CAR_1 and CAR_2 may pass in or out of the first and second carriers CAR_1 and CAR_2.

The first carrier gate CG_1 of the first carrier CAR_1 seated on the first carrier port CP_1 may face the first device gate EG_1. Therefore, the first material MAT_1 in the first carrier CAR_1 seated on the first carrier port CP_1 may sequentially pass the first carrier gate CG_1 and the first device gate EG_1, and may be loaded into the first processing device PE_1. A material on which a process is completely performed in the first processing device PE_1 may sequentially pass the first device gate EG_1 and the first carrier gate CG_1, and may be received in the first carrier CAR_1.

The second carrier gate CG_2 of the second carrier CAR_2 seated on the second carrier port CP_2 may face the second device gate EG_2. Therefore, the second material MAT_2 in the second carrier CAR_2 seated on the second carrier port CP_2 may sequentially pass the second carrier gate CG_2 and the second device gate EG_2, and may be loaded into the second processing device PE_2. A material on which a process is completely performed in the second processing device PE_2 may sequentially pass the second device gate EG_2 and the second carrier gate CG_2, and may be received in the second carrier CAR_2.

The overhead hoist transfer system OHT including the rotating unit RU may freely dispose a plurality of various processing devices PE_1 and PE_2, which are disposed at locations adjacent to the rail RL, regardless of a direction in which the carrier ports CP_1 and CP_2 and the device gates EG_1 and EG_2 are arranged. For example, since different processing devices PE_1 and PE_2, on which different processes are performed, are disposed to be adjacent to each other, the carriers CAR_1 and CAR_2 may be rotated to a desired direction, and the materials are provided and/or received to/from the different processing devices PE_1 and PE_2 using the same overhead hoist transfer system OHT, transport times of the logistics thereof and the efficiency in performing the process may be improved, while an inner space of the factory system FAB may be effectively used.

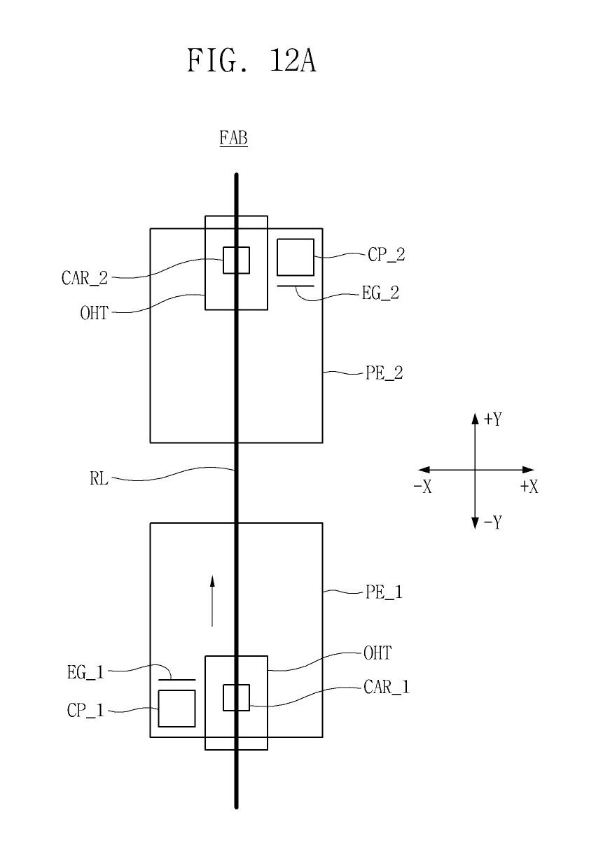

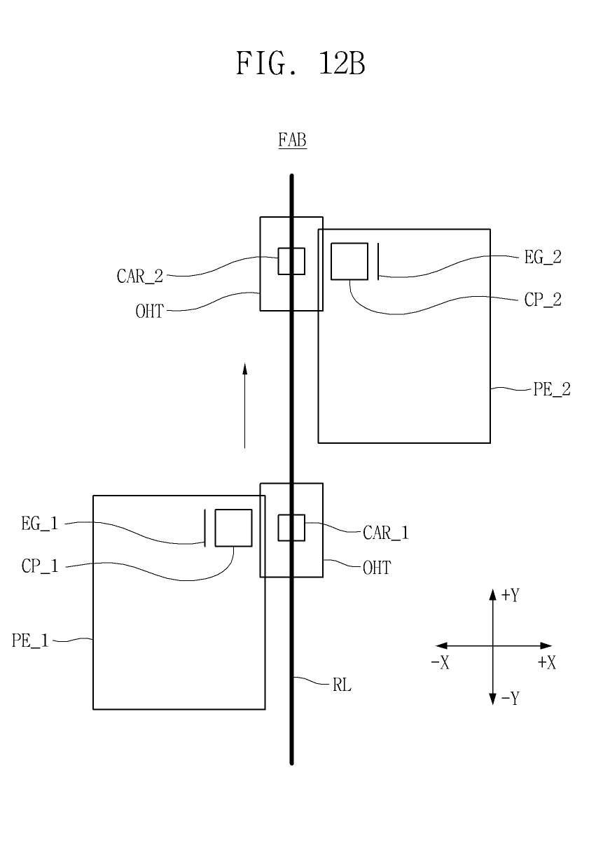

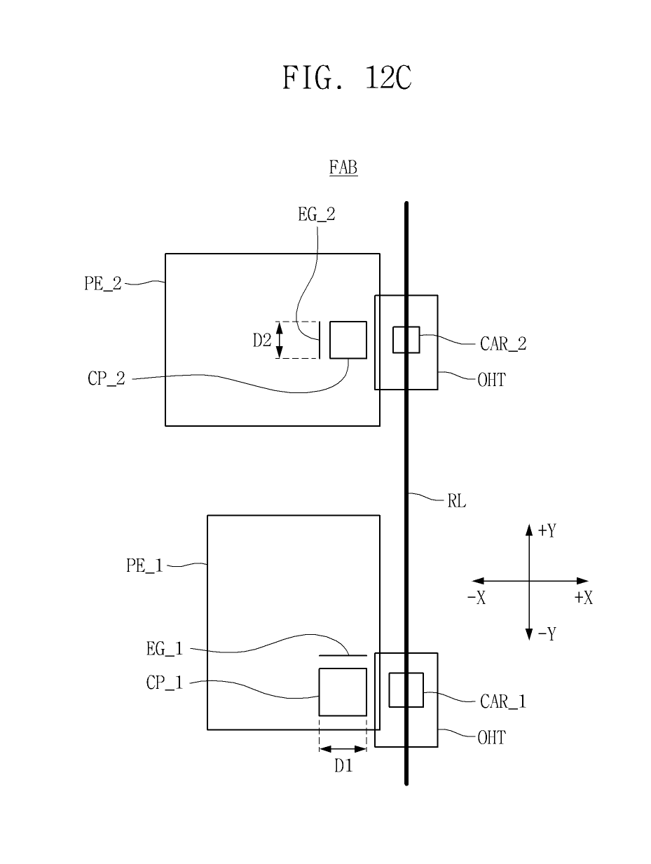

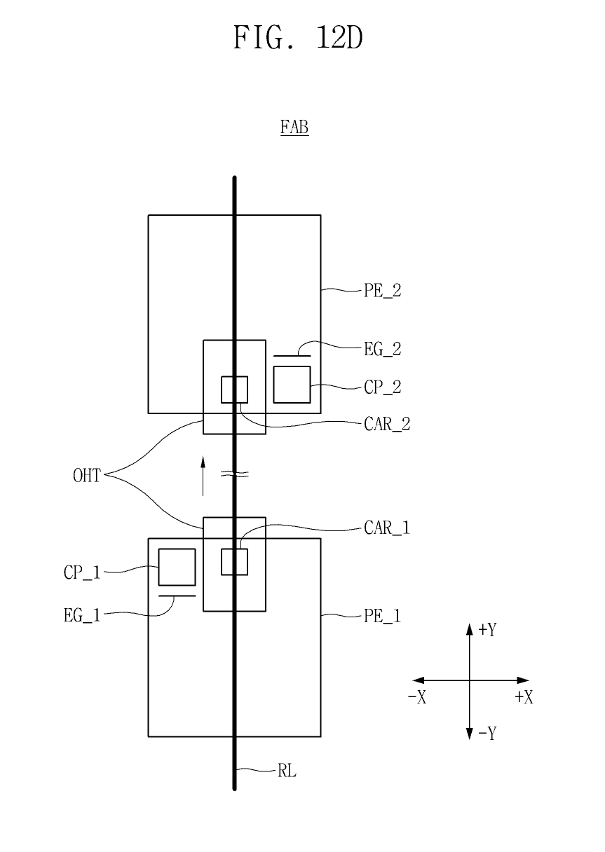

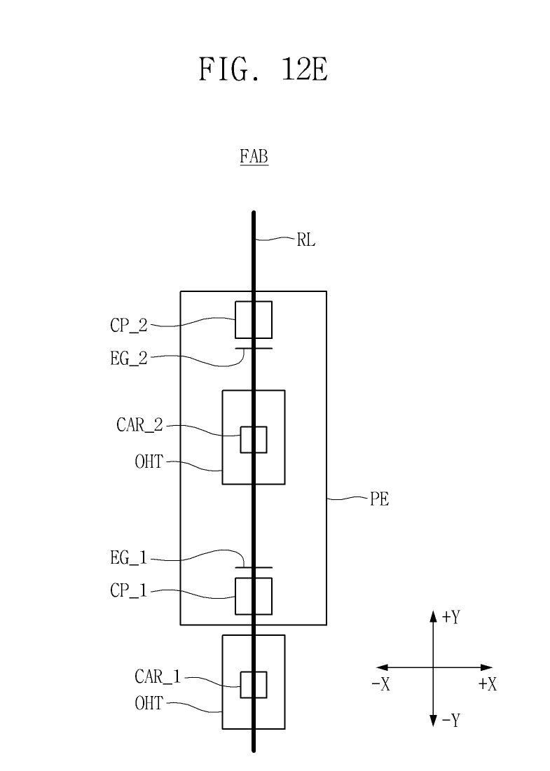

The overhead hoist transfer system OHT capable of moving and rotating the first carrier CAR_1 or the second carrier CAR_2 will be described with reference to FIGS. 2 to 11, and arrangements of the carrier ports CP_1 and CP_2 and the device gates EG_1 and EG_2 will be described with reference to FIGS. 12A to 12E.

An overhead hoist transfer system OHT_1 in accordance with an exemplary embodiment will be described with reference to FIG. 2. FIG. 2 is a schematic block diagram showing the overhead hoist transfer system OHT_1 in accordance with an exemplary embodiment.

Referring to FIGS. 1 and 2, the overhead hoist transfer system OHT_1 in accordance with an exemplary embodiment may include a drive unit VU1, a body BU1, a sliding unit SU1, a hoist unit HU1, a rotating unit RU1, a grip unit GU1, and a control system CS1.

The drive unit VU1 may drive along the rail RL of the factory system FAB. The body BU1 may be disposed under the drive unit VU1, and connected to the drive unit VU1. The sliding unit SU1 may be connected to the body BU1. The hoist unit HU1 may be disposed under the sliding unit SU1. The rotating unit RU1 may be disposed under the hoist unit HU1. The grip unit GU1 may be disposed under the rotating unit RU1. The grip unit GU1 may hold the first carrier CAR_1 (shown in FIG. 1) and/or the second carrier CAR_2 (shown in FIG. 1). The control system CS1 may include a communication device, sensors, and a control device to operate or manage the overhead hoist transfer system OHT_1.

The rotating unit RU1 may be connected to the grip unit GU1, and may rotate the grip unit GU1. For example, the rotating unit RU1 may rotate the grip unit GU1 by “−90° to −270 °,” “−180° to +180°,” or “−270° to +90 °.”

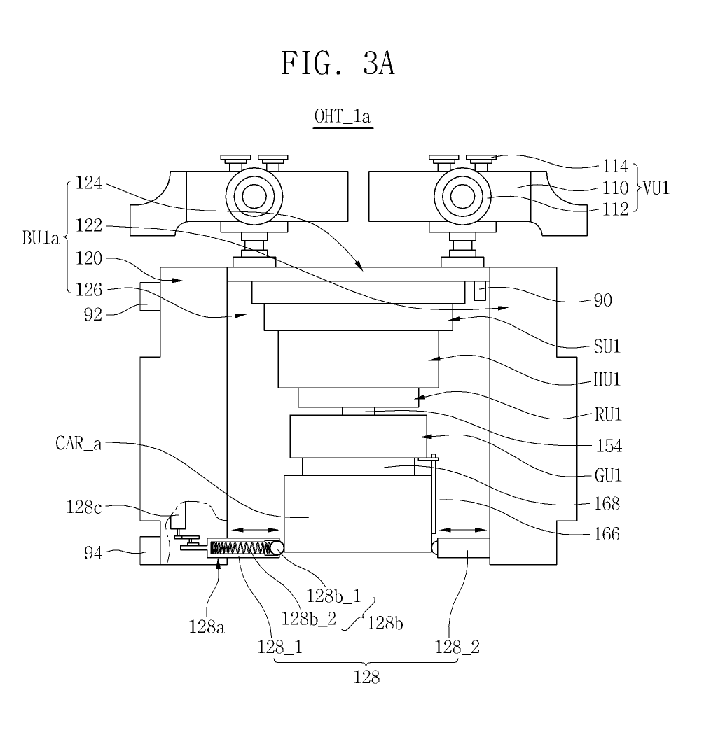

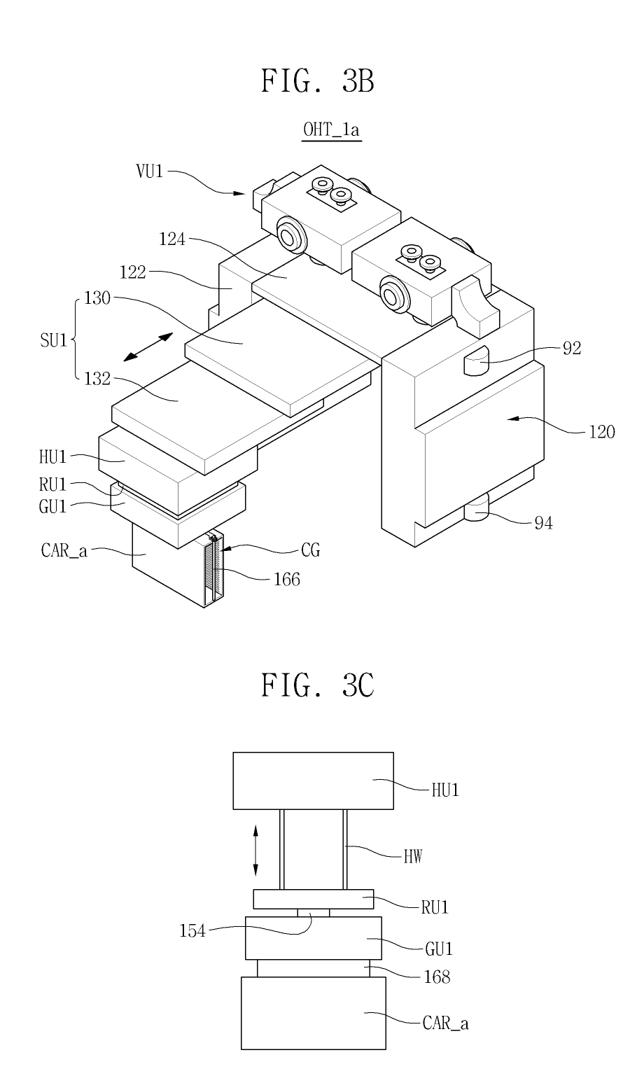

An example of the overhead hoist transfer system OHT_1 described in FIG. 2 will be described with reference to FIGS. 3A, 3B, and 3C. FIG. 3A is a side view showing an overhead hoist transfer system OHT_1a in accordance with an exemplary embodiment, FIG. 3B is a perspective view showing the overhead hoist transfer system OHT_1a in accordance with an exemplary embodiment, and FIG. 3C is a view showing a part of the overhead hoist transfer system OHT_1a in accordance with an exemplary embodiment.

Referring to FIGS. 1, 2, 3A, 3B, and 3C, the overhead hoist transfer system OHT_1a in accordance with an exemplary embodiment may include a drive unit VU1, a body BU1a, a sliding unit SU1, a hoist unit HU1, a rotating unit RU1, a grip unit GU1, and a control system CS1.

The drive unit VU1 may drive and move along the rail RL. The drive unit VU1 may include a drive base 110, drive wheels 112 disposed on two sides of the drive base 110, and a turning converter 114 disposed on the drive base 110. The drive wheel 112 may have a part in direct contact with the rail RL.

The body BU1a may be disposed under the drive unit VU1, and connected to the drive unit VU1. The body BU1a may include a front body part 120, a rear body part 122, and an upper body part 124.

The body BU1a may have an inner space 126 in which two sides and a bottom of the body BU1a are open. The inner space 126 of the body BU1a may be defined by the upper body part 124, the front body part 120, and the rear body part 122. The upper body part 124 may be directly connected to the drive unit VU1 in an exemplary embodiment. The front body part 120 and the rear body part 122 may face each other. The upper body part 124 may be disposed between an upper part of the front body part 120 and an upper part of the rear body part 122. The upper body part 124 may be connected to an upper end of the front body part 120 and an upper end of the rear body part 122.

The sliding unit SU1 may be located in the inner space 126 of the body BU1a, and connected to the upper body part 124. The sliding unit SU1 may be located under the upper body part 124, and between the front body part 120 and the rear body part 122.

The sliding unit SU1 may include a sliding plate configured to slide from the inner space 126 of the body BU1a to a desired side of the open two sides thereof and move the grip unit GU1 disposed under the sliding unit SU1 to outside the body BU1a. For example, the sliding plate of the sliding unit SU1 may include an upper sliding plate 130, and a lower sliding plate 132 disposed under the upper sliding plate 130.

When the overhead hoist transfer system OHT_1a moves along the rail RL, the sliding unit SU1, as described in FIG. 3A, may be located in the inner space 126 of the body BU1a.

When the overhead hoist transfer system OHT_1a reaches a desired location, for example, after the overhead hoist transfer system OHT_1a reaches and stops at a location adjacent to a desired carrier port of the first and second carrier ports CP_1 and CP_2, the sliding unit SU1 operates, and ends of the sliding plates 130 and 132 may slide and move to a desired side of the open two sides of the body BU1a, as described in FIG. 3B. The grip unit GU1 may be located on a desired carrier port of the first and second carrier ports CP_1 and CP_2 by the operation of the sliding unit SU1.

The hoist unit HU1 may be disposed under the sliding unit SU1, and connected to a lower part of the lower sliding plate 132 of the sliding unit SU1. The hoist unit HU1 may include a hoist wire HW.

When the sliding unit SU1 operates and the grip unit GU1 is located at the desired carrier port of the first and second carrier ports CP_1 and CP_2, the hoist unit HU1 operates, and the grip unit GU1 may be lowered in a direction of the desired carrier port of the first and second carrier ports CP_1 and CP_2. The hoist wire HW of the hoist unit HU1 may be released by an operation of a drive motor of the hoist unit HU1 operating according to a control of the control system CS1, and may lower the grip unit GU1. In an exemplary embodiment, the hoist wire HW may be wound by the operation of the drive motor of the hoist unit HU1 operating according to the control of the control system CS1, and may raise the lowered grip unit GU1.

The rotating unit RU1 may be disposed between the hoist unit HU1 and the grip unit GU1. The rotating unit RU1 may be connected to the hoist unit HU1. The rotating unit RU1 may be connected to the hoist wire HW of the hoist unit HU1.

The grip unit GU1 may include a holding part 168 capable of holding or releasing a carrier CAR_a. The holding part 168 of the grip unit GU1 may hold or release an upper part of the carrier CAR_a. The carrier CAR_a may be the first carrier CAR_1 or the second carrier CAR_2 described in FIG. 1.

The overhead hoist transfer system OHT_1a may include a carrier fixing device 128. The carrier fixing device 128 may be disposed in the body BU1a. The carrier fixing device 128 may include a first carrier fixing device 128_1 disposed in a lower area of the front body part 120, and a second carrier fixing device 128_2 disposed in a lower area of the rear body part 122.

Each of the first and second carrier fixing devices 128_1 and 128_2 may include a carrier fixing part 128a, a buffer part 128b, and a drive part for a carrier fixing device 128c.

The carrier fixing part 128a may be disposed to move in a direction from an inside of the front body part 120 or an inside of the rear body part 122 to a carrier CAR_a, and may have a hollow rod shape. A horizontal double-headed arrow shown in FIG. 3A shows that the carrier fixing part 128a may move in horizontally reciprocating directions.

The buffer part 128b may include a ball 128b_1 disposed on an end of the carrier fixing part 128a beside the carrier CAR_a, and an elastic body 128b_2 disposed in a hollow inside of the carrier fixing part 128a. The elastic body 128b_2 may have a coil spring. In an exemplary embodiment, only a part of the ball 128b_1 may protrude from the end of the carrier fixing part 128a and not fall from the end of the carrier fixing part 128a. The ball 128b_1 may be connected to the elastic body 128b_2. The drive part for the carrier fixing device 128c may include a motor and/or gear capable of moving the carrier fixing part 128a in horizontally reciprocating directions.

When the grip unit GU1 holding the carrier CAR_a is located in the inner space 126 of the body BU1a, the carrier CAR_a is fixed by operating the first and second carrier fixing devices 128_1 and 128_2. Thus, the carrier CAR_a may be prevented from being shaken in a process in which the overhead hoist transfer system OHT_1a moves along the rail RL. For example, when the grip unit GU1 holding the carrier CAR_a is located in the inner space 126 of the body BU1a, the control system CS1 may operate the drive part for the carrier fixing device 128c, and horizontally move the carrier fixing part 128a in a direction toward the carrier CAR_a until the ball 128b_1 of the buffer part 128b contacts the carrier CAR_a. The buffer part 128b may relieve an impact applied to the carrier CAR_a.

To place the carrier CAR_a to any one carrier port of the first carrier port CP_1 and the second carrier port CP_2 in the processing device system PE, the overhead hoist transfer system OHT_1a may be moved to a location adjacent to the any one carrier port of the first and second carrier ports CP_1 and CP_2 and stopped. Before the sliding unit SU1 and the hoist unit HU1 operate, the control system CS1 may operate the drive part for the carrier fixing device 128c, and move the carrier fixing part 128a in a direction away from the carrier CAR_a so that the ball 128b_1 of the buffer part 128b is spaced apart from the carrier CAR_a.

The control system CS1 may include a front side detecting sensor 92, a lower side detecting sensor 94, and a control device 90. The front side detecting sensor 92 may have a sensor for detecting any other object located in front of the overhead hoist transfer system OHT_1a, for example, another overhead hoist transfer system located in front thereof. For example, when the another overhead hoist transfer system located in front thereof is stopped while the overhead hoist transfer system OHT_1a moves, the front side detecting sensor 92 may detect the another overhead hoist transfer system located in front thereof. Thus, the control system CS1 may stop the overhead hoist transfer system OHT_1a according to a detected signal, and avoid a collision with the another overhead hoist transfer system located in front thereof.

The lower side detecting sensor 94 may include a sensor capable of detecting an unexpected object or operator located under the overhead hoist transfer system OHT_1a. For example, when an operator is under the overhead hoist transfer system OHT_1a, the lower side detecting sensor 94 detects the operator, and transmits a detecting signal to the control system CS1. The control system CS1 may stop an operation of the overhead hoist transfer system OHT_1a. Thus, the operator may be prevented from being injured by the overhead hoist transfer system OHT_1a.

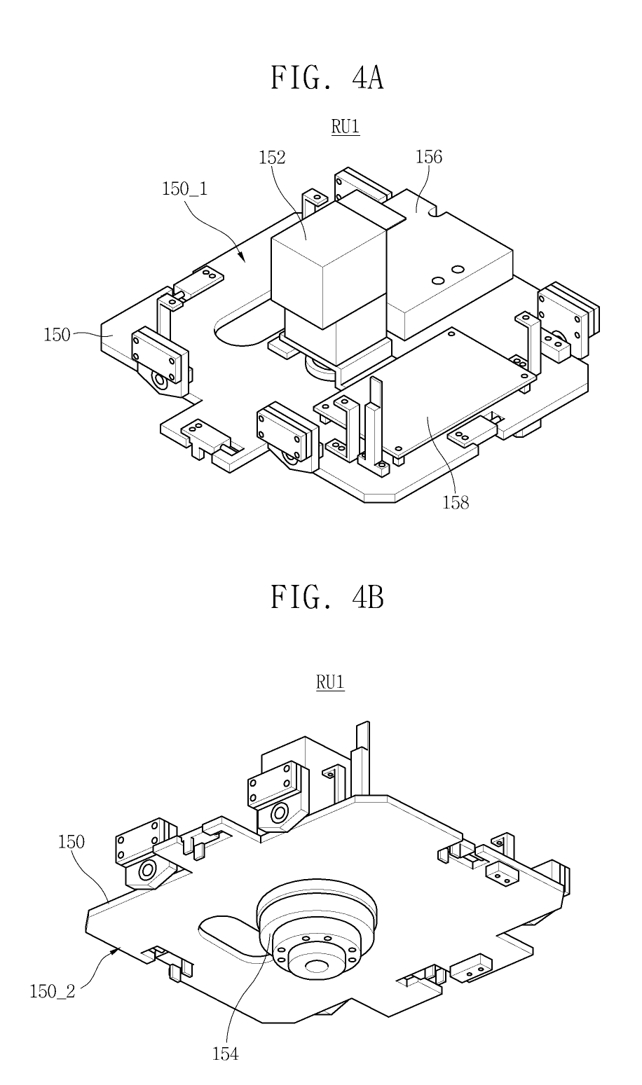

FIGS. 4A and 4B are perspective views for describing an internal structure of the rotating unit RU1 of the overhead hoist transfer system in accordance with exemplary embodiments. The rotating unit RU1 shown in FIGS. 3A, 3B, and 3C has a shape wrapped by a cover.

Referring to FIGS. 4A and 4B, the rotating unit RU1 may include a rotating base 150 having a first side 150_1 and a second side 150_2 facing the first side 150_1, a rotating drive device 152 disposed on the first side 150_1 of the rotating base 150, and a rotating shaft 154 protruding from the second side 150_2 of the rotating base 150. The rotating drive device 152 may have a device such as a drive motor or the like. The rotating shaft 154 may be connected to the rotating drive device 152, and may be rotated according to an operation of the rotating drive device 152.

The rotating unit RU1 may include a sensor 156 disposed on the first side 150_1 of the rotating base 150, and a rotating control part 158. The sensor 156 may have a programmed input/output (PIO) sensor. The sensor 156 and the rotating control part 158 may be included in the control system CS1.

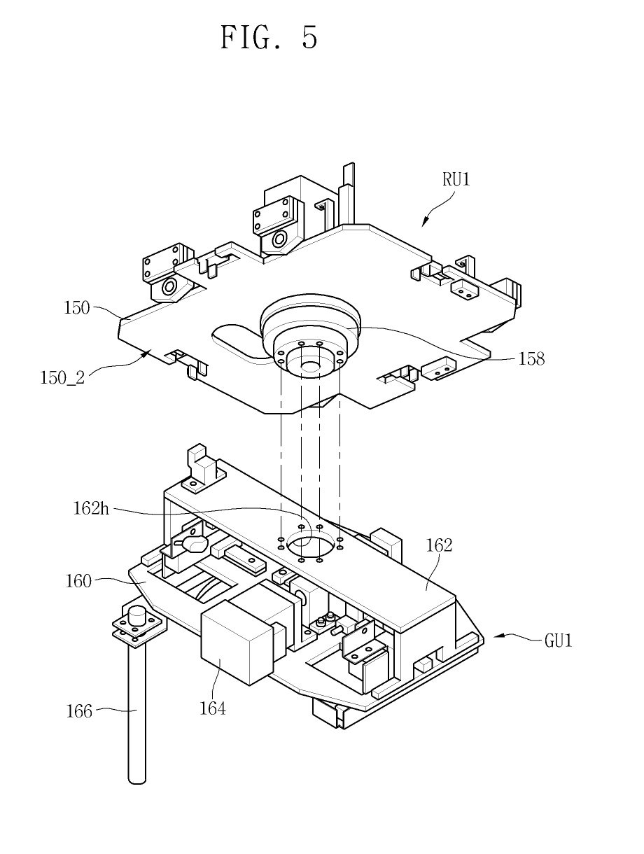

FIG. 5 is a perspective view for describing the rotating unit RU1 and the grip unit GU1 of the overhead hoist transfer system in accordance with an exemplary embodiment. FIG. 5 shows the rotating unit RU1 as shown in FIGS. 4A and 4B according to exemplary embodiments. FIG. 5 shows a part of a cover 162 of the grip unit GU1 to describe an inside of the grip unit GU1.

Referring to FIGS. 1, 2, 3A, 3B, 3C, and 5, the grip unit GU1 may include a grip base 160, a grip drive device 164 disposed on the grip base 160, and an anti-protruding material 166 connected to the grip drive device 164. The grip drive device 164 may include a drive unit such as a motor or the like.

A movement of the anti-protruding material 166 may be controlled by the control system CS1. After the grip unit GU1 holds the carrier CAR_a, the anti-protruding material 166 may move to block a front of a carrier gate CG of the carrier CAR_a. Therefore, the anti-protruding material 166 may prevent the materials MAT_1 and MAT_2 (shown in FIG. 1) loaded in the carrier CAR_a from being damaged by an inside of the carrier CAR_a while the overhead hoist transfer system OHT_1a moves or drives.

The grip unit GU1 may include a grip cover 162 covering the grip drive device 164 of the grip base 160. The grip cover 162 may be connected and fixed to the grip base 160. The grip cover 162 may have a coupling groove 162h. The coupling groove 162h of the grip cover 162 may be connected and held to the rotating shaft 154 of the rotating unit RU1. Therefore, the grip drive device 164 may rotate by a rotation of the rotating shaft 154.

Subsequently, an overhead hoist transfer system in accordance with an exemplary embodiment will be described with reference to FIGS. 1, 2, 6A, and 6B.

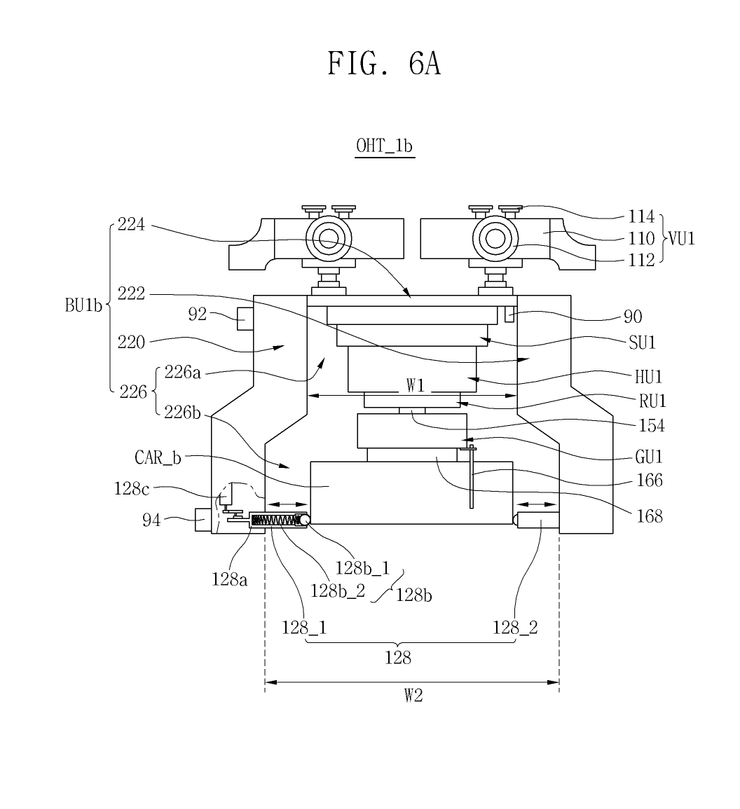

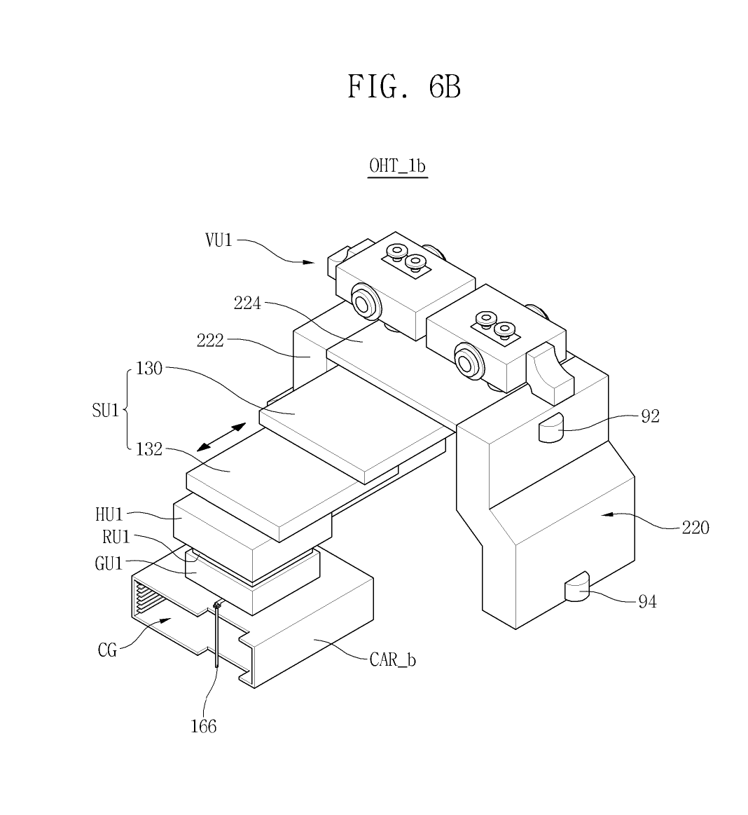

FIG. 6A is a side view showing an overhead hoist transfer system in accordance with an exemplary embodiment, and FIG. 6B is a perspective view showing the overhead hoist transfer system in accordance with an exemplary embodiment.

Referring to FIGS. 1, 2, 6A, and 6B, the overhead hoist transfer system OHT_1b in accordance with an exemplary embodiment may include a drive unit VU1, a body BU1b, a sliding unit SU1, a hoist unit HU1, a rotating unit RU1, a grip unit GU1, a carrier fixing device 128, and a control system CS1.

The drive unit VU1, the sliding unit SU1, the rotating unit RU1, the carrier fixing device 128, and the control system CS1 may be substantially the same as those described in FIGS. 3A and 3B.

The body BU1b may be disposed under the drive unit VU1, and connected to the drive unit VU1. The body BU_1b may include a front body part 220, a rear body part 222, and an upper body part 224. The upper body part 224 may be directly connected to the drive unit VU1. The front body part 220 and the rear body part 222 may face each other. The upper body part 224 may be disposed between an upper part of the front body part 220 and an upper part of the rear body part 222. The upper body part 224 may be connected to an upper end of the front body part 220 and an upper end of the rear body part 222.

The body BU1b may have an inner space 226, in which two sides and a bottom of the body BU1b are open. The inner space 226 of the body BU1b may be defined by the upper body part 224, the front body part 220, and the rear body part 222.

The inner space 226 of the body BU1b may have a first space 226a having a first width W1, and a second space 226b having a second width W2 greater than the first width W1. The second space 226b may be located under the first space 226a.

A carrier CAR_b suspended by the grip unit GU1 may be located in the second space 226b of the body BU1b. The carrier CAR_b may be the first carrier CAR_1 or the second carrier CAR_2 described in FIG. 1. The carrier CAR_b may receive a material such as a semiconductor wafer or the like. In a top view, the second width W2 of the second space 226b in the inner space 226 may be greater than a diagonal length of the carrier CAR_b. The carrier fixing device 128 may be located in the body BU1b to fix the carrier CAR_b located in the second space 226b.

The rotating unit RU1 operates before the sliding unit SU1 and the hoist unit HU1 operate. After the carrier CAR_b suspended by the grip unit GU1 is first rotated with the grip unit GU1, the sliding unit SU1 and the hoist unit HU1 operate, and thus the carrier CAR_b may be seated on a desired carrier port of the first and second carrier ports CP_1 and CP_2.

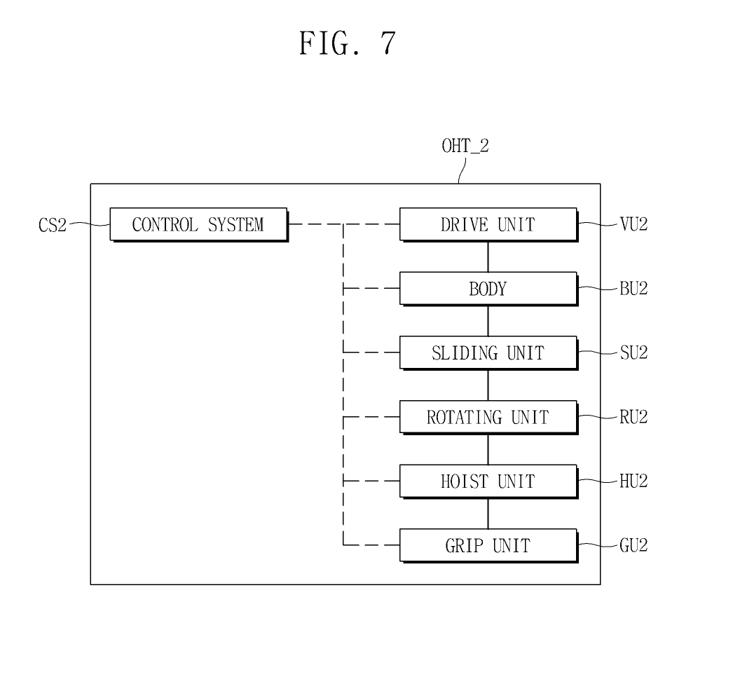

An overhead hoist transfer system OHT_2 in accordance with an exemplary embodiment will be described with reference to FIGS. 1 and 7. FIG. 7 is a schematic block diagram showing the overhead hoist transfer system OHT_2 in accordance with an exemplary embodiment.

Referring to FIGS. 1 and 7, the overhead hoist transfer system OHT_2 in accordance with an exemplary embodiment may include a drive unit VU2, a body BU2, a sliding unit SU2, a hoist unit HU2, a rotating unit RU2, a grip unit GU2, and a control system CS2.

The drive unit VU2 may drive along the rail RL of the factory system FAB. The body BU2 may be disposed under the drive unit VU2, and connected to the drive unit VU2. The sliding unit SU2 may be connected to the body BU2. The rotating unit RU2 may be disposed under the sliding unit SU2. The hoist unit HU2 may be disposed under the rotating unit RU2. The grip unit GU2 may be disposed under the hoist unit HU2. The grip unit GU2 may grip the first carrier CAR_1 and/or the second carrier CAR_2. The control system CS2 may include a communication device, a sensor, and a control device to operate or manage the overhead hoist transfer system OHT_2.

The rotating unit RU2 may rotate the grip unit GU2. For example, the rotating unit RU2 may rotate the grip unit GU2 by 360°. For example, the rotating unit RU2 may rotate the grip unit GU2 by “−90° to −270 °,” “−180° to +180°,” or “−270° to +90 °.”

The rotating unit RU2 may be disposed between the sliding unit SU2 and the hoist unit HU2.

The rotating unit RU2 may be substantially the same as the rotating unit RU1 described in FIGS. 4A and 4B. Therefore, the rotating unit RU2 may include the rotating shaft 158 (shown in FIG. 4B). The rotating shaft 158 (shown in FIG. 4B) of the rotating unit RU2 may be connected to one of the sliding unit SU2 and the hoist unit HU2.

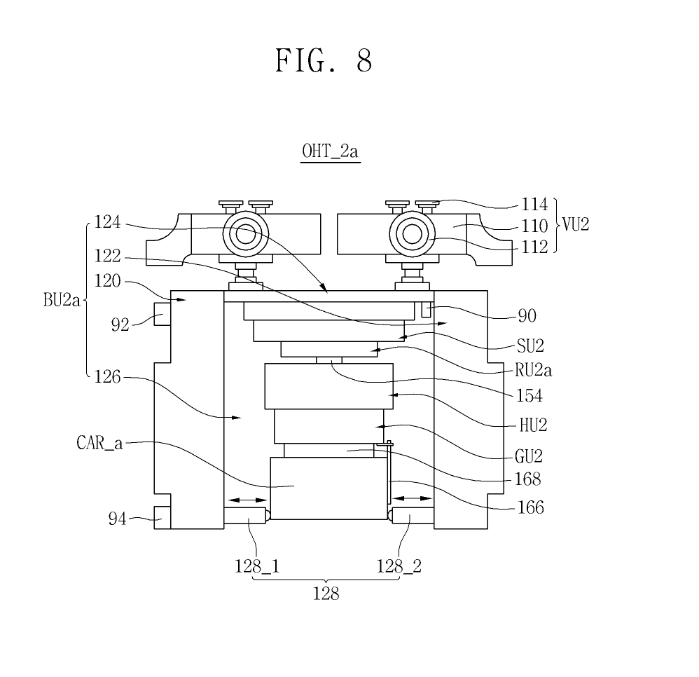

An example OHT_2a of the overhead hoist transfer system OHT_2 described in FIG. 7 will be described with reference to FIG. 8. FIG. 8 is a side view showing the overhead hoist transfer system OHT_2a in accordance with an exemplary embodiment.

Referring to FIGS. 7 and 8, the overhead hoist transfer system OHT_2a in accordance with an exemplary embodiment may include a drive unit VU2, a body BU2a, a sliding unit SU2, a rotating unit RU2a, a hoist unit HU2, a grip unit GU2, and a control system CS2.

The drive unit VU2, the body BU2a, and the sliding unit SU2 may be substantially the same as the drive unit VU1, the body BU1a, and the sliding unit SU1 described in FIGS. 3A and 3B.

The rotating unit RU2a may be disposed under the sliding unit SU2. The hoist unit HU2 may be disposed under the rotating unit RU2a. The grip unit GU2 may be disposed under the hoist unit HU2.

The rotating unit RU2a may be the same as the rotating unit RU1 described in FIGS. 4A and 4B. Therefore, the rotating unit RU2a may include the rotating shaft 154.

The rotating shaft 154 of the rotating unit RU2a may be connected to an upper part of the hoist unit HU2. Therefore, the hoist unit HU2 and the grip unit GU2 disposed under the hoist unit HU2 may be rotated by the rotating shaft 154 of the rotating unit RU2a.

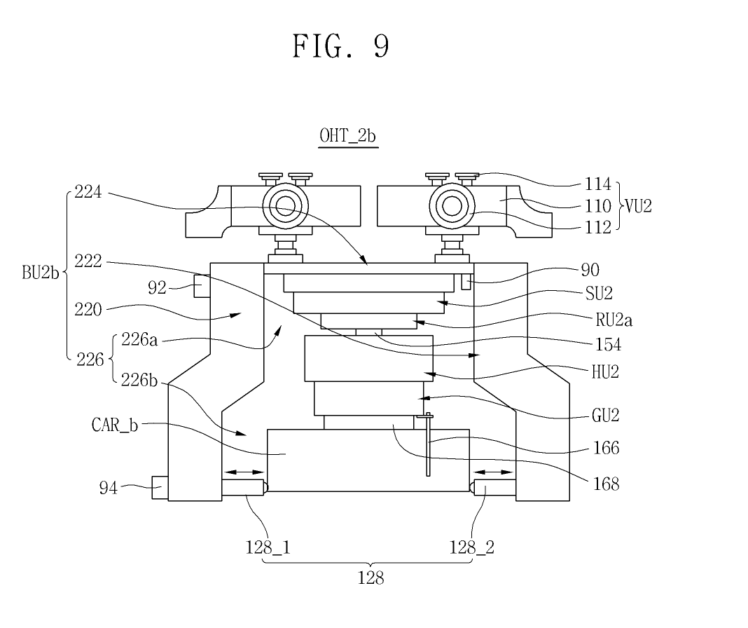

An example OHT_2b of the overhead hoist transfer system OHT_2 described in FIG. 7 will be described with reference to FIG. 9. FIG. 9 is a side view showing the overhead hoist transfer system OHT_2b in accordance with an exemplary embodiment.

Referring to FIGS. 7 and 9, the overhead hoist transfer system OHT_2b in accordance with an exemplary embodiment may include a drive unit VU2, a sliding unit SU2, a rotating unit RU2a, a hoist unit HU2, a grip unit GU2, and a control system CS2.

The overhead hoist transfer system OHT_2b may include a body BU2b substantially the same as the body BU1b described in FIGS. 6A and 6B. Therefore, the body BU2b may include a front body part 220, a rear body part 222 facing the front body part 220, and an upper body part 224 configured to connect upper parts of the front side to rear body parts 220 and 222. Further, the body BU2b may have an inner space 226, in which two sides and a bottom of the body BU2b are open. The inner space 226 of the body BU2b, as described in FIGS. 6A and 6B, may have a first space 226a having a first width, and a second space 226b having a second width greater than the first width.

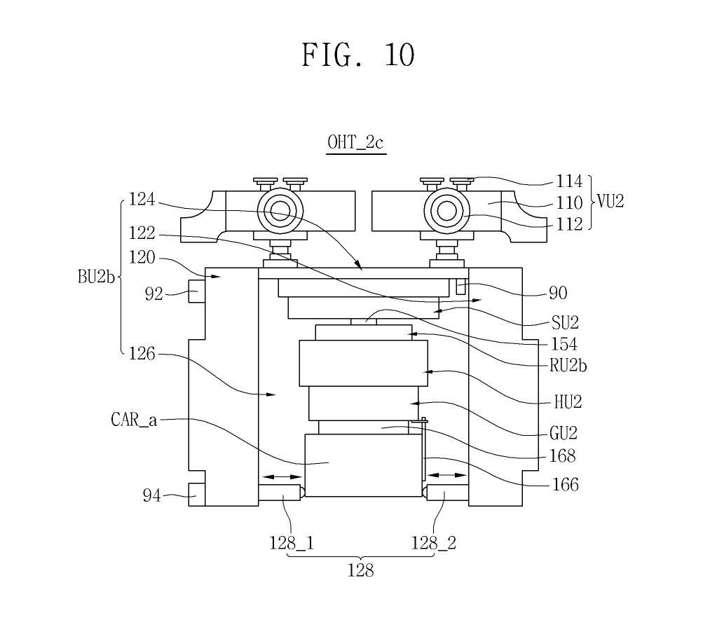

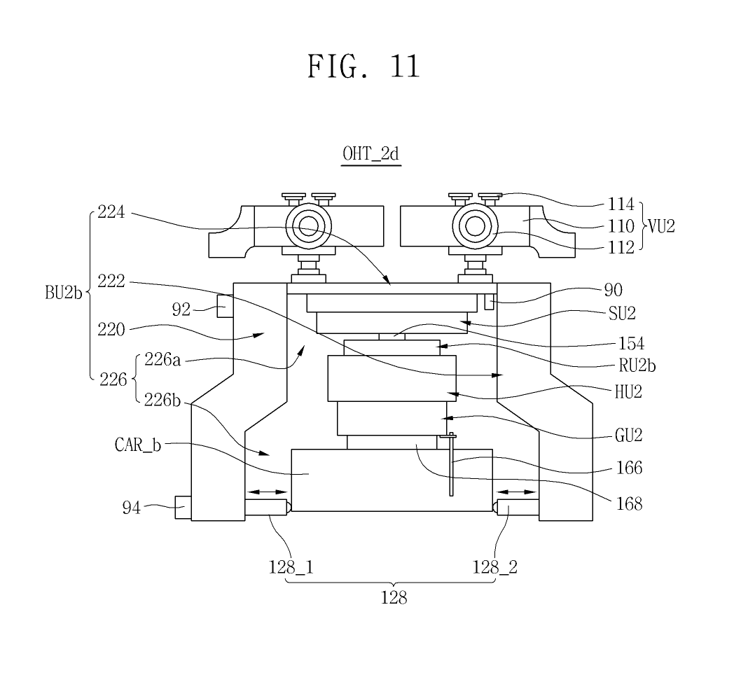

An example OHT_2c of the overhead hoist transfer system OHT_2 described in FIG. 7 will be described with reference to FIG. 10. FIG. 10 is a side view showing the overhead hoist transfer system OHT_2c in accordance with an exemplary embodiment.

Referring to FIGS. 7 and 10, the overhead hoist transfer system OHT_2c in accordance with an exemplary embodiment may include a drive unit VU2, a body BU2b, a sliding unit SU2, a rotating unit RU2b, a hoist unit HU2, a grip unit GU2, and a control system CS2.

The drive unit VU2, the body BU2b, the sliding unit SU2, the hoist unit HU2, the grip unit GU2, and the control system CS2 may be substantially the same as those described in FIG. 8.

The rotating unit RU2b may be the same as the rotating unit RU1 described in FIGS. 4A and 4B. Therefore, the rotating unit RU2b may include the rotating shaft 154.

The rotating shaft 154 of the rotating unit RU2b may be connected to a lower part of the sliding unit SU2. Therefore, the rotating unit RU2b, the hoist unit HU2 and the grip unit GU2 disposed under the hoist unit HU2 may be rotated by the rotating shaft 154 of the rotating unit RU2b.

An example OHT_2d of the overhead hoist transfer system OHT_2 described in FIG. 7 will be described with reference to FIG. 11. FIG. 11 is a side view showing the overhead hoist transfer system OHT_2d in accordance with an exemplary embodiment.

Referring to FIGS. 7 and 11, the overhead hoist transfer system OHT_2d in accordance with an exemplary embodiment may include a drive unit VU2, a sliding unit SU2, a rotating unit RU2b, a hoist unit HU2, a grip unit GU2, and a control system CS2.

The drive unit VU2, the sliding unit SU2, the hoist unit HU2, the grip unit GU2, and the control system CS2 may be substantially the same as those described in FIG. 8.

The overhead hoist transfer system OHT_2d may include a body BU2b substantially the same as the body BU1b described in FIGS. 6A and 6B. Therefore, the body BU2b may include a front body part 220, a rear body part 222 facing the front body part 220, and an upper body part 224 configured to connect upper parts of the front side to rear body parts 220 and 222. The body BU2b may have an inner space 226, in which two sides and a bottom of the body BU2b are open. The inner space 226 of the body BU2b, as described in FIGS. 6A and 6B, may have a first space 226a having a first width, and a second space 226b having a second width greater than the first width.

As described in FIG. 1, the processing device system PE may include the first processing device PE_1 having the first carrier port CP_1 and the first device gate EG_1, and the second processing device PE_2 having the second carrier port CP_2 and the second device gate EG_2. An arrangement of the first and second carrier ports CP_1 and CP_2 and the first and second device gates EG_1 and EG_2 in the factory system FAB will be described with reference to FIGS. 12A to 12E.

In FIGS. 12A to 12E, a direction to which the overhead hoist transfer system OHT moves along the rail RL may be defined as a “+Y direction,” and an opposite direction thereof may be defined as a “−Y direction.” A direction perpendicular to the “+Y direction” and extending to the left may be defined as a “−X direction,” and a direction perpendicular to the “+Y direction” and extending to the right may be defined as a “+X direction.”

Referring to FIGS. 1 and 12A, the overhead hoist transfer system OHT may be any one of the overhead hoist transfer systems OHT described in FIGS. 2 to 11. The overhead hoist transfer system OHT may move in the “+Y direction” along the rail RL.

The first carrier port CP_1 and the first device gate EG_1 may be sequentially arranged in the “+Y direction.” A direction from the first carrier port CP_1 to the first device gate EG_1 may be the “+Y direction.”

The first carrier port CP_1 and the first device gate EG_1 may be sequentially arranged in the same direction as a moving direction of the overhead hoist transfer systems OHT. In a plane view, the first carrier port CP_1 and the first device gate EG_1 may be located in the “−X direction” based on the rail RL, and spaced apart from the rail RL.

The second carrier port CP_2 and the second device gate EG_2 may be sequentially arranged in the “−Y direction.” A direction from the second carrier port CP_2 to the second device gate EG_2 may be the “−Y direction.” The second carrier port CP_2 and the second device gate EG_2 may be sequentially arranged in a direction opposite to the moving direction of the overhead hoist transfer systems OHT. In a plan view, the second carrier port CP_2 and the second device gate EG_2 may be located in the “+X direction” based on the rail RL, and spaced apart from the rail RL. In a plan view, the second carrier port CP_2 and the second device gate EG_2 may be located to the opposite of the first carrier port CP_1 and the first device gate EG_1 based on the rail RL.

A direction (e.g., +Y direction) from the first carrier port CP_1 to the first device gate EG_1 may be different from a direction (e.g., −Y direction) from second carrier port CP_2 to the second device gate EG_2. The direction from the first carrier port CP_1 to the first device gate EG_1 may be different from the direction from the second carrier port CP_2 to the second device gate EG_2 by 180 °.

The rotating unit RU of the overhead hoist transfer systems OHT may rotate the first carrier CAR_1 so that the first carrier gate CG_1 of the first carrier CAR_1 faces the first device gate EG_1, and the second carrier CAR_2 so that the second carrier gate CG_2 of the second carrier CAR_2 faces the second device gate EG_2.

Referring to FIGS. 1 and 12B, the overhead hoist transfer system OHT may be any one of the overhead hoist transfer systems OHT described in FIGS. 2 to 11. The overhead hoist transfer system OHT may move in the “+Y direction” along the rail RL.

The first carrier port CP_1 and the first device gate EG_1 may be sequentially arranged in the “−X direction.” The first carrier port CP_1 and the first device gate EG_1 may be sequentially arranged in a direction perpendicular to the moving direction of the overhead hoist transfer systems OHT. In a plan view, the first carrier port CP_1 and the first device gate EG_1 may be located in the “−X direction” based on the rail RL. In a plan view, the first carrier port CP_1 and the first device gate EG_1 may be spaced apart from the rail RL.

The second carrier port CP_2 and the second device gate EG_2 may be sequentially arranged in the “+X direction.” The second carrier port CP_2 and the second device gate EG_2 may be sequentially arranged in the direction perpendicular to the moving direction of the overhead hoist transfer systems OHT. In a plan view, the second carrier port CP_2 and the second device gate EG_2 may be located in the “+X direction” based on the rail RL. The second carrier port CP_2 and the second device gate EG_2 may be spaced apart from the rail RL. In a plan view, the second carrier port CP_2 and the second device gate EG_2 may be disposed to the opposite of the first carrier port CP_1 and the first device gate EG_1 based on the rail RL.

A direction from the first carrier port CP_1 to the first device gate EG_1 may be different from a direction from second carrier port CP_2 to the second device gate EG_2. The direction from the first carrier port CP_1 to the first device gate EG_1 may be different from the direction from second carrier port CP_2 to the second device gate EG_2 by 180 °.

Referring to FIGS. 1 and 12C, the overhead hoist transfer system OHT may be any one of the overhead hoist transfer systems OHT described in FIGS. 2 to 11. The overhead hoist transfer system OHT may move in the “+Y direction” along the rail RL.

The first carrier port CP_1 and the first device gate EG_1 may be sequentially arranged in the “+Y direction.” The first carrier port CP_1 and the first device gate EG_1 may be sequentially arranged in the same direction as a moving direction of the overhead hoist transfer systems OHT. In a plan view, the first carrier port CP_1 and the first device gate EG_1 may be located in the “−X direction” based on the rail RL. In a plan view, the first carrier port CP_1 and the first device gate EG_1 may be spaced apart from the rail RL.

The second carrier port CP_2 and the second device gate EG_2 may be sequentially arranged in the “−X direction.” The second carrier port CP_2 and the second device gate EG_2 may be sequentially arranged in the direction perpendicular to the moving direction of the overhead hoist transfer systems OHT. In a plan view, the second carrier port CP_2 and the second device gate EG_2 may be located in the “−X direction” based on the rail RL. The second carrier port CP_2 and the second device gate EG_2 may be spaced apart from the rail RL.

A direction from the first carrier port CP_1 to the first device gate EG_1 may be different from a direction from second carrier port CP_2 to the second device gate EG_2. The direction from the first carrier port CP_1 to the first device gate EG_1 may be different from the direction from second carrier port CP_2 to the second device gate EG_2 by 90° or 270 °.

In some exemplary embodiments, the first device gate EG_1 may have a first size D1 so that the first material MAT_1 may be passed in and out of the first device gate EG_1, and the second device gate EG_2 may have a second size D2 different from the first size D1 so that the second material MAT_2 may be passed in and out of the second device gate EG_2. The first material MAT_1 may be a semiconductor wafer, and the second material MAT_2 may be a semiconductor die, a semiconductor chip, or a printed circuit board. For example, the first processing device PE_1 having the first carrier port CP_1 and the first device gate EG_1 may be a processing device in which a semiconductor wafer is used for the first material MAT_1, and the second processing device PE_2 having the second carrier port CP_2 and the second device gate EG_2 may be a processing device in which a semiconductor die, a semiconductor chip, or a printed circuit board, which is divided by cutting a semiconductor wafer, is used for the second material MAT_2. For example, the first processing device PE_1 may be a device for a sawing process, in which the semiconductor wafer is cut, or a pre-sawing process and the second processing device PE_2 may be a device for a die attaching process (D/A), in which the semiconductor wafer is divided by the sawing process, or a post-D/A process.

Referring to FIGS. 1 and 12D, the overhead hoist transfer system OHT may be any one of the overhead hoist transfer systems OHT described in FIGS. 2 to 11. The overhead hoist transfer system OHT may move in the “+Y direction” along the rail RL.

The first carrier port CP_1 and the first device gate EG_1 may be sequentially arranged in the “−Y direction.” The second carrier port CP_2 and the second device gate EG_2 may be sequentially arranged in the “+Y direction.” Therefore, a direction from the first carrier port CP_1 to the first device gate EG_1 may be different from a direction from the second carrier port CP_2 to the second device gate EG_2.

In a plan view, the second carrier port CP_2 and the second device gate EG_2 may be disposed to face the first carrier port CP_1 and the first device gate EG_1 based on the rail RL, respectively.

Referring to FIGS. 1 and 12E, the first and second carrier ports CP_1 and CP_2 and the first and second device gate EG_1 and EG_2 may be disposed in one processing device system PE.

The first carrier port CP_1 and the first device gate EG_1, as described in FIG. 12A, may be sequentially arranged in the “+Y direction.” The second carrier port CP_2 and the second device gate EG_2, as described in FIG. 12A, may be sequentially arranged in the “−Y direction.” Therefore, a direction from the first carrier port CP_1 to the first device gate EG_1 may be different from a direction from the second carrier port CP_2 to the second device gate EG_2. In a plan view, the first and second carrier ports CP_1 and CP_2 and the first and second device gate EG_1 and EG_2 may overlap the rail RL.

In accordance with the exemplary embodiments, the overhead hoist transfer system driving along a rail attached to a ceiling of a factory may be provided. The overhead hoist transfer system may include the grip unit capable of gripping and suspending the carrier, and the rotating unit capable of rotating the grip unit. The overhead hoist transfer system including the rotating unit may freely dispose a plurality of various processing devices, which are disposed at locations adjacent to the rail, regardless of a direction of the carrier port, in which the carrier is seated, and the device gate, in which the material is passed in and out. For example, since different processing devices, on which different processes are performed, are disposed to be adjacent to each other, and the materials are provided and/or received to/from the different processing devices using the same overhead hoist transfer system, transport times of the logistics thereof and the efficiency in performing the process may be improved, while an inner space of the factory system can be effectively used.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of exemplary embodiments as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A system comprising:
a rail attached to a ceiling of a factory;
an overhead hoist transfer system in which a first carrier configured to receive a first material or a second carrier configured to receive a second material is suspended and moved along the rail; and
a processing device system including a first carrier port in which the first carrier is seated, a first device gate through which the first material passes, a second carrier port in which the second carrier is seated, and a second device gate through which the second material passes, the processing device system being adjacent to the rail,
wherein the overhead hoist transfer system includes a grip unit configured to grip the first carrier or the second carrier, and a rotating unit configured to rotate the grip unit.

2. The system according to claim 1, wherein a first direction from the first carrier port to the first device gate is different from a second direction from the second carrier port to the second device gate.

3. The system according to claim 1, wherein the first device gate has a first size to allow the first material to be passed in and out of the first device gate and the second device gate has a second size different from the first size to allow the second material to be passed in and out of the second device gate, and the first material comprises a semiconductor wafer and the second material comprises at least one from among a semiconductor die, a semiconductor chip, and a printed circuit board.

4. The system according to claim 1, wherein the overhead hoist transfer system further comprises:
a drive unit configured to drive along the rail;
a body connected to the drive unit and having an inner space in which a bottom portion and two side portions of the body are open;
a sliding unit connected to the body; and
a hoist unit disposed under the sliding unit.

5. The system according to claim 4, wherein the hoist unit is connected to the rotating unit.

6. The system according to claim 4, wherein the rotating unit includes a rotating shaft and a rotary drive motor configured to rotate the rotating shaft, and the rotating shaft of the rotating unit is connected to the grip unit.

7. An overhead hoist transfer system comprising:
a drive unit;
a body connected at a lower part of the drive unit;
a sliding unit connected to the body;
a grip unit disposed under the sliding unit and configured to hold a carrier; and
a hoist unit and a rotating unit, the hoist unit and the rotating unit being disposed between the sliding unit and the grip unit, and connected to each other.

8. The overhead hoist transfer system according to claim 7, wherein the body has an inner space in which two side portions and a bottom portion of the body are open.

9. The overhead hoist transfer system according to claim 8, wherein the body includes a front body part, a rear body part facing the front body part, and an upper body part connecting an upper part of the front body part to an upper part of the rear body part.

10. The overhead hoist transfer system according to claim 9, further comprising:
a control system,
wherein the control system includes a front side detecting sensor and a lower side detecting sensor, which are disposed on the front body part.

11. The overhead hoist transfer system according to claim 9, further comprising:
a carrier fixing device connected to the body,
wherein the carrier fixing device includes a first carrier fixing device disposed in a lower area of the front body part, and a second carrier fixing device disposed in a lower area of the rear body part.

12. The overhead hoist transfer system according to claim 11, wherein each of the first and second carrier fixing devices includes a drive part, a carrier fixing part, and a buffer part, and the drive part is disposed on the body, the carrier fixing part has a part protruding from the body and is disposed to move in horizontally reciprocating directions by the drive part, and the buffer part has a part, which contacts the carrier by a horizontal reciprocating motion of the carrier fixing part.

13. The overhead hoist transfer system according to claim 8, wherein the inner space of the body has a first space having a first width and a second space having a second width greater than the first width.

14. The overhead hoist transfer system according to claim 13, wherein the sliding unit is disposed in the first space, and the carrier held by the grip unit is located in the second space.

15. The overhead hoist transfer system according to claim 8, wherein the sliding unit includes a sliding plate configured to move to a desired side of the open two side portions of the body, the hoist unit includes a hoist wire configured to lower or raise the grip unit, and the rotating unit includes a rotary drive motor and a rotating shaft, the rotary drive motor being configured to directly or indirectly rotate the grip unit.

16. The overhead hoist transfer system according to claim 7, wherein one of the hoist unit and the rotating unit is connected to the sliding unit, and another one of the hoist unit and the rotating unit is connected to the grip unit.

17. An overhead hoist transfer system, comprising:
a drive unit configured to drive along a rail attached to a ceiling of a facility;
a body connected at a lower part of the drive unit and having an inner space in which a bottom portion and two side portions of the body are open;
a sliding unit connected to the body and disposed in the inner space of the body;
a grip unit disposed under the sliding unit, and configured to hold a carrier, in which a material is loaded, the grip unit being located in the inner space of the body; and
a hoist unit and a rotating unit, which are disposed between the sliding unit and the grip unit and connected to each other.

18. The overhead hoist transfer system according to claim 17, wherein the rotating unit is disposed between the grip unit and the hoist unit, and directly connected to the grip unit.

19. The overhead hoist transfer system according to claim 18, wherein the rotating unit includes a rotating shaft and a rotary drive motor configured to rotate the rotating shaft.

20. The overhead hoist transfer system according to claim 17, further comprising:
a carrier fixing device connected to the body,
wherein the carrier fixing device includes a carrier fixing part protruding from the body to face the carrier located in the inner space of the body, a drive unit disposed inside the body and configured to move the carrier fixing part in horizontally reciprocating directions, and a buffer part including a part formed on an end of the carrier fixing part and directly contacting the carrier by a horizontal reciprocating motion of the carrier fixing part.
